(19) United States
(12) Patent Application Publication
(10) Pub. No.: US 2010/0080001 A1
(43) Pub. Date: Apr. 1, 2010

(54) SEMICONDUCTOR LASER DEVICE AND DISPLAY

(75) Inventors: Yasumitsu KUNOH, Hirakata-shi (JP); Yasuhiko NOMURA, Osaka-shi (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi-shi (JP)

(21) Appl. No.: 12/568,356

(22) Filed: Sep. 28, 2009

(30) Foreign Application Priority Data
Sep. 30, 2008 (JP) 2008-254553
Aug. 28, 2009 (JP) 2009-198146

(51) Int. Cl. G02B 27/18; H01S 5/30; H01S 5/20

(52) U.S. Cl. 362/259; 372/45.011; 372/44.011

(57) ABSTRACT

This semiconductor laser device includes a substrate, a green semiconductor laser element, formed on a surface of the substrate, including a first active layer having a first major surface of a semipolar plane and a blue semiconductor laser element, formed on a surface of the substrate, including a second active layer having a second major surface of a surface of the semipolar plane, while the first active layer includes a first well layer having a compressive strain and having a thickness of at least about 3 nm, and the second active layer includes a second well layer having a compressive strain.

### CROSS-REFERENCE TO RELATED APPLICATIONS

The priority application numbers JP2008-254553, semiconductor laser device, Sep. 30, 2008, Yasumitsu Kunoh et al. and JP2009-198146, semiconductor laser device, Aug. 28, 2009, Yasumitsu Kunoh et al., upon which this patent application is based are hereby incorporated by reference.

### BACKGROUND OF THE INVENTION

1. Field of the Invention

The present invention relates to a semiconductor laser device and a display, and more particularly, it relates to a semiconductor laser device including blue and green semiconductor laser elements formed on the surface of the same substrate and a display including the same.

2. Description of the Background Art

While miniaturization of a device such as a projector has recently been increasingly required, development of a projector and a display each employing semiconductor laser elements as red (R), G (green) and B (blue) light sources for obtaining white light is advanced. In order to miniaturize the device and to reduce the number of components constituting the same, it is attempted to employ semiconductor laser elements capable of directly utilizing the wavelengths of light sources as the light sources. In the case of employing the semiconductor laser elements as the light sources, employment of a monolithic double-wavelength semiconductor laser device prepared by forming a blue semiconductor laser element and a green semiconductor laser element included in semiconductor laser elements of the three colors R, G, and B on the same substrate is also attempted. Such a semiconductor laser device is disclosed in Japanese Patent Laying-Open No. 2007-227652, for example.

The aforementioned Japanese Patent Laying-Open No. 2007-227652 discloses a monolithic double-wavelength semiconductor light-emitting device (semiconductor laser device) prepared by forming a green semiconductor laser element including a first active layer of InGaN and a blue semiconductor laser element including a second active layer of InGaN on the surface of the same substrate. Japanese Patent Laying-Open No. 2007-227652 neither discloses nor suggests which crystal planes are employed for defining the major surfaces when forming the first active layer of the green semiconductor laser element and the second active layer of the blue semiconductor laser element.

In the double-wavelength semiconductor light-emitting device disclosed in the aforementioned Japanese Patent Laying-Open No. 2007-227652, however, piezoelectric fields generated by piezoelectric polarization resulting from strains of crystal lattices are increased if the first and second active layers are formed on a c-plane ((0001) plane) which is a polar plane, and hence luminous efficiencies of the green and blue semiconductor laser elements are disadvantageously reduced.

In order to suppress reduction in the luminous efficiencies of the blue and green semiconductor laser elements, therefore, the active layers may be formed on a major surface of a semipolar plane (plane inclined with respect to a c-plane) such as a (11-22) plane or a (1-101) plane, of the substrate. If the active layers are formed on a major surface of a semipolar plane, however, vibrator strength has anisotropy with respect to light polarized in the plane since the semipolar plane has small symmetry of an in-plane crystal structure as compared with the c-plane. As to the green semiconductor laser element having a large anisotropic compressive strain in the plane due to an In content larger than that in the blue semiconductor laser element and having a large oscillation wavelength, a direction of polarization having large vibrator strength may rotate by 90°. As to this point, it is reported in Extended Abstracts of the 55^{th} Lecture Meeting of the Japan Society of Applied Physics and Related Societies, 29a-B-8, that the direction of polarization rotates by 90° when the thickness of a well layer in an active layer is small in a blue-green semiconductor light-emitting element having an oscillation wavelength (about 490 nm) larger than that of a blue semiconductor light-emitting element. From this report, it is conceivable that the direction of polarization may rotate also in a green semiconductor light-emitting element having a larger In content and a larger oscillation wavelength (about 500 nm to about 565 nm) than the blue semiconductor light-emitting element similarly to the blue-green semiconductor light-emitting element, when the thickness of a well layer in an active layer is small.

When a monolithic double-wavelength semiconductor laser device is prepared by forming blue and green semiconductor laser elements including active layers having major surfaces of semipolar planes on the surface of the same substrate in the aforementioned case, the direction of polarization of high vibrator strength in the major surface in emission from the active layer of the blue semiconductor laser element and the direction of polarization of high vibrator strength in the major surface in emission from the active layer of the green semiconductor laser element differ from each other. Therefore, such a problem may conceivably arise that the extensional directions of light guides maximizing optical gains of the blue and green semiconductor laser elements are not matched with each other. The extensional directions of the light guides maximizing the optical gains are perpendicular to the directions of maximum polarization of the vibrator strength in the planes.

### SUMMARY OF THE INVENTION

The inventor has made deep studies in order to solve the aforementioned problem, to find that the extensional directions of light guides maximizing optical gains of green and blue semiconductor laser elements can be substantially matched with each other by setting the thickness of a first well layer having a compressive strain to at least about 3 nm in the green semiconductor laser element including the first active layer having a major surface of a semipolar plane through various considerations. In other words, a semiconductor laser device according to a first aspect of the present invention includes a substrate, a green semiconductor laser element, formed on a surface of the substrate, including a first active layer having a first major surface of a semipolar plane and a blue semiconductor laser element, formed on a surface of the substrate, including a second active layer having a second major surface of a surface orientation substantially identical to the semipolar plane, while the first active layer includes a first well layer having a compressive strain and having a thickness of at least about 3 nm, and the second active layer includes a second well layer having a compressive strain. The term “green semiconductor laser element” denotes a semiconductor laser element having an oscillation wavelength in the range of about 500 nm to about 565 nm. In the present invention, the term “thickness” denotes the thickness of a single well layer when the corresponding active layer has a single quantum well (SQW) structure, and denotes the thickness of each of a plurality of well layers constituting a multiple quantum well (MQW) structure when the corresponding active layer has the MQW structure. The term “compressive strain” denotes a strain resulting from compressive force caused by the difference between the lattice constants of an underlayer and the corresponding well layer. The compressive strain is caused when the corresponding well layer is grown in pseudo-lattice matching with the substrate in a state where the in-plane lattice constant of the well layer in an unstrained state is larger as compared with that of the substrate in an unstrained state or when the well layer is grown in pseudo-lattice matching on a layer (cladding or barrier layer) having a smaller in-plane lattice constant as compared with that of the unstrained well layer, for example.

In the semiconductor laser device according to the first aspect of the present invention, as hereinabove described, the first well layer of the first active layer, having the first major surface of the semipolar plane, of the green semiconductor laser element is formed to have the thickness of at least about 3 nm, whereby the extensional directions of light guides maximizing optical gains of the blue and green semiconductor laser elements can be substantially matched with each other when the first active layer of the green semiconductor laser element and the second active layer of the blue semiconductor laser element formed on the first and second major surfaces of semipolar planes having substantially identical surface orientations with each other.

In the aforementioned semiconductor laser device according to the first aspect, the first active layer and the second active layer are preferably made of nitride-based semiconductors. According to this structure, green and blue semiconductor laser elements having higher efficiencies can be prepared.

In the aforementioned semiconductor laser device according to the first aspect, the first well layer is preferably made of a nitride-based semiconductor containing In, and is more preferably made of InGaN. According to this structure, a green semiconductor laser element having a higher efficiency can be prepared.

In the aforementioned semiconductor laser device including the first well layer made of InGaN, an In composition in the first well layer is preferably at least about 30%. According to this structure, the extensional directions of the light guides maximizing the optical gains of the blue and green semiconductor laser elements can be substantially matched with each other.

In the aforementioned semiconductor laser device including the first well layer having the In composition of at least about 30%, the In composition in the first well layer is preferably at least about 33%, and the first well layer preferably has a thickness of at least about 3.5 nm. According to this structure, the extensional directions of the light guides maximizing the optical gains of the blue and green semiconductor laser elements can be substantially matched with each other.

In the aforementioned semiconductor laser device according to the first aspect, the second well layer is preferably made of a nitride-based semiconductor containing In, and is more preferably made of InGaN. According to this structure, a blue semiconductor laser element having a higher efficiency can be prepared.

In the aforementioned semiconductor laser device according to the first aspect, the first well layer and the second well layer are preferably made of nitride-based semiconductors containing In, and an In composition in the first well layer is preferably larger than an In composition in the second well layer. According to this structure, the extensional directions of the light guides maximizing the optical gains of the blue and green semiconductor laser elements can be substantially matched with each other.

In the aforementioned semiconductor laser device according to the first aspect, a thickness of the first well layer is preferably larger than a thickness of the second well layer. In the green and blue semiconductor laser elements including the first and second active layers having the first and second major surfaces of the semipolar planes, respectively, the extensional direction of the light guide maximizing the optical gain conceivably more hardly changes in the blue semiconductor laser element having a smaller compressive strain in the active layer and a smaller oscillation wavelength than the green semiconductor laser element, and hence the thickness of the second well layer of the second active layer of the blue semiconductor laser element can be rendered smaller than the thickness of the first well layer of the first active layer of the green semiconductor laser element. Thus, the second active layer of the blue semiconductor laser element can be prevented from formation of misfit dislocations resulting from different lattice constants of the crystal lattices of the second well layer and an underlayer on which the second well layer is grown.

In the aforementioned semiconductor laser device according to the first aspect, the semipolar plane is preferably a plane inclined toward a (0001) plane or a (000-1) plane by at least about 10° and not more than about 70°. According to this structure, the extensional directions of the light guides maximizing the optical gains of the green and blue semiconductor laser elements can be more reliably matched with each other.

In this case, the semipolar plane is preferably substantially a (11-22) plane. According to this structure, reduction in luminous efficiencies of the green and blue semiconductor laser elements can be more suppressed due to piezoelectric fields smaller than those of other semipolar planes.

In the aforementioned semiconductor laser device according to the first aspect, the substrate preferably has a major surface of a surface orientation substantially identical to the semipolar plane. According to this structure, the green and blue semiconductor laser elements including the first and second active layers having the first and second major surfaces of the semipolar planes, respectively can be easily formed by simply growing semiconductor layers on the substrate having the major surface of the surface orientation of the semipolar plane substantially identical to those defining the first and second major surfaces of the first and second active layers of the green and blue semiconductor laser elements.

In the aforementioned semiconductor laser device including the first and second active layers made of the nitride-based semiconductors, the substrate is preferably made of a nitride-based semiconductor. According to this structure, the green and blue semiconductor laser elements including the first and second active layers made of the nitride-based semiconductors can be easily formed by simply growing semiconductor layers on the substrate made of the nitride-based semiconductor.

In this case, the first well layer is preferably made of InGaN having a first major surface of the semipolar plane, the second well layer is preferably made of InGaN having a second major surface of the semipolar plane, and the substrate is preferably made of GaN having a major surface of the semipolar plane. According to this structure, the green and blue semiconductor laser elements including the first and second active layers made of InGaN having the first and second major surfaces of the semipolar planes, respectively, can be easily formed by simply growing semiconductor layers on the substrate of GaN having the major surface of the semipolar plane identical to those defining the first and second major surfaces of the first and second active layers of the green and blue semiconductor laser elements.

In the aforementioned semiconductor laser device according to the first aspect, the green semiconductor laser element and the blue semiconductor laser element preferably further include light guides extending in directions projecting [0001] directions on the major surfaces of semipolar planes. In order to maximize the optical gains of the semiconductor laser elements, the light guides must be formed perpendicularly to main directions of polarization of emission from the active layers. In other words, the optical gains of the green and blue semiconductor laser elements can be maximized while a green beam of the green semiconductor laser element and a blue beam of the blue semiconductor laser element can be emitted from a common cavity facet by forming the light guides in the directions projecting the [0001] directions on the major surfaces of the semipolar planes.

In the aforementioned semiconductor laser device according to the first aspect, the green semiconductor laser element preferably further includes a first light guide layer containing In formed on at least either a side of one surface or a side of another surface of the first active layer, the blue semiconductor laser element preferably further includes a second light guide layer containing In formed on at least either a side of one surface or a side of another surface of the second active layer, and an In composition in the first light guide layer is preferably larger than an In composition in the second light guide layer. According to this structure, the first light guide layer can more confine light in the first active layer than the second light guide layer, whereby the green beam emitted from the green semiconductor laser element can be more confined in the first active layer. Thus, the green semiconductor laser element inferior in luminous efficiency as compared with the blue semiconductor laser element can ensure light confinement to an extent similar to that of the blue semiconductor laser element.

In the aforementioned semiconductor laser device according to the first aspect, the green semiconductor laser element preferably further includes a first carrier blocking layer containing Al formed on at least either a side of one surface or a side of another surface of the first active layer, the blue semiconductor laser element preferably further includes a second carrier blocking layer containing Al formed on at least either a side of one surface or a side of another surface of the second active layer, and an Al composition in the first carrier blocking layer is preferably larger than an Al composition in the second carrier blocking layer. According to this structure, the first carrier blocking layer can more confine light in the first active layer than the second carrier blocking layer, whereby the green beam emitted from the green semiconductor laser element can be more confined in the first active layer. Thus, the green semiconductor laser element inferior in luminous efficiency as compared with the blue semiconductor laser element can ensure light confinement to an extent similar to that of the blue semiconductor laser element.

In the aforementioned semiconductor laser device according to the first aspect, the green semiconductor laser element preferably further includes a first cladding layer containing Al formed on at least either a side of one surface or a side of another surface of the first active layer, the blue semiconductor laser element further includes a second cladding layer containing Al formed on at least either a side of one surface or a side of another surface of the second active layer, and an Al composition in the first cladding layer is preferably larger than an Al composition in the second cladding layer. According to this structure, the first cladding layer can more confine light in the first active layer than the second cladding layer, whereby the green beam emitted from the green semiconductor laser element can be more confined in the first active layer. Thus, the green semiconductor laser element inferior in luminous efficiency as compared with the blue semiconductor laser element can ensure light confinement to an extent similar to that of the blue semiconductor laser element.

The aforementioned semiconductor laser device according to the first aspect preferably further includes a red semiconductor laser element bonded to at least any of the blue semiconductor laser element, the green semiconductor laser element and the substrate. The term “red semiconductor laser element” denotes a semiconductor laser element having an oscillation wavelength in the range of about 610 nm to about 750 nm. According to this structure, an RGB triple-wavelength semiconductor laser device including a blue/green double-wavelength semiconductor laser element portion including the blue and green semiconductor laser elements matching the extensional directions of the light guides maximizing the optical gains with each other and the red semiconductor laser element can be obtained.

In this case, the red semiconductor laser element is preferably bonded to the substrate in a junction-down manner. According to this structure, heat generated in an active layer of the red semiconductor laser element can be radiated on the substrate, whereby an RGB triple-wavelength semiconductor laser device including a red semiconductor laser element having a higher luminous efficiency can be prepared.

A display according to a second aspect of the present invention includes a semiconductor laser device including a substrate, a green semiconductor laser element, formed on a surface of the substrate, including a first active layer having a first major surface of a semipolar plane and a blue semiconductor laser element, formed on a surface of the substrate, including a second active layer having a second major surface of a surface orientation substantially identical to the semipolar plane and means for modulating light emitted from the semiconductor laser device, while the first active layer includes a first well layer having a compressive strain and having a thickness of at least about 3 nm, and the second active layer includes a second well layer having a compressive strain.

In the display according to the second aspect of the present invention, as hereinabove described, the first well layer of the first active layer, having the first major surface of the semipolar plane, of the green semiconductor laser element is formed to have the thickness of at least about 3 nm, whereby the display can display a desired image by employing the semiconductor laser device substantially matching the extensional directions of light guides maximizing optical gains of the green and blue semiconductor laser elements with each other and modulating light with the modulation means when the first active layer of the green semiconductor laser element and the second active layer of the blue semiconductor laser element formed on the surface of the same substrate have first and second major surfaces of semipolar planes having substantially identical surface orientations with each other.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing the structure of a semiconductor laser device according to a first embodiment of the present invention;

FIG. 2 is a diagram for illustrating the crystal structure and surface orientations of GaN and directions of polarization of a semiconductor laser element;

FIG. 3 is an enlarged sectional view showing the structure of an active layer of a blue semiconductor laser element of the semiconductor laser device according to the first embodiment shown in FIG. 1;

FIG. 4 is an enlarged sectional view showing the structure of an active layer of a green semiconductor laser element of the semiconductor laser device according to the first embodiment shown in FIG. 1;

FIGS. 5 to 7 are diagrams for illustrating a process for manufacturing the semiconductor laser device according to the first embodiment shown in FIG. 1;

FIG. 8 is a sectional view showing the structure of a semiconductor laser device according to a second embodiment of the present invention;

FIG. 9 is a schematic diagram showing a projector including the semiconductor laser device according to the second embodiment shown in FIG. 8 and cyclically turning on semiconductor laser elements in a time-series manner;

FIG. 10 is a timing chart showing a state where a control portion of the projector according to the second embodiment shown in FIG. 9 transmits signals in a time-series manner; and

FIG. 11 is a schematic diagram showing another projector including the semiconductor laser device according to the second embodiment shown in FIG. 8 and substantially simultaneously turning on the semiconductor laser elements.

### DESCRIPTION OF THE PREFERRED EMBODIMENTS

Embodiments of the present invention are described with reference to the drawings.

### First Embodiment

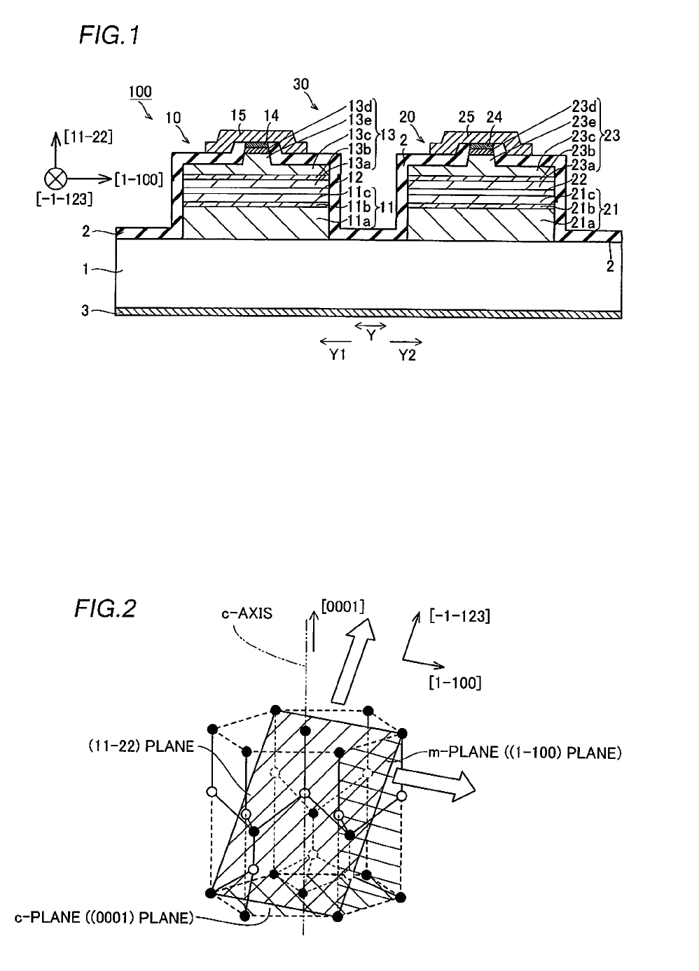

The structure of a semiconductor laser device 100 according to a first embodiment of the present invention is now described with reference to FIGS. 1 to 4.

In the semiconductor laser device 100 according to the first embodiment, a monolithic blue/green double-wavelength semiconductor laser element portion 30 consisting of a blue semiconductor laser element 10 having an oscillation wavelength of about 450 nm and a green semiconductor laser element 20 having an oscillation wavelength of about 530 nm is formed on an n-type GaN substrate 1 having a thickness of about 100 μm, as shown in FIG. 1. The blue semiconductor laser element 10 has an oscillation wavelength in the range of about 435 nm to about 485 nm. The green semiconductor laser element 20 has an oscillation wavelength in the range of about 500 nm to about 565 nm. The n-type GaN substrate 1 is an example of the “substrate” in the present invention.

The monolithic blue/green double-wavelength semiconductor laser element portion 30 is formed on the n-type GaN substrate 1 having a major surface of a (11-22) plane (see FIG. 2). As shown in FIG. 2, the (11-22) plane is a semipolar plane inclined from a c-plane ((0001) plane) toward a [11-20] direction by about 58°. A semipolar plane inclined from the c-plane by at least about 10° and not more than about 70° is preferably employed, in order to substantially match the extensional directions of light guides, described later, maximizing optical gains of the green and blue semiconductor laser elements 20 and 10 with each other. The (11-22) plane has a smaller piezoelectric field as compared with other semipolar planes, whereby reduction in luminous efficiencies of the blue and green semiconductor laser elements 10 and 20 can be suppressed. Thus, the (11-22) plane is more preferably employed.

As shown in FIG. 1, the blue semiconductor laser element 10 has a structure obtained by stacking an n-type semiconductor layer 11, an active layer 12 and a p-type semiconductor layer 13 as semiconductor layers in this order on a region of the upper surface of the n-type GaN substrate 1 on the side of a [−1100] direction (direction Y1). The green semiconductor laser element 20 has a structure obtained by stacking an n-type semiconductor layer 21, an active layer 22 and a p-type semiconductor layer 23 as semiconductor layers in this order on a region of the upper surface of the same n-type GaN substrate 1 as the blue semiconductor laser element 10 on the side of a [1-100] direction (direction Y2). The active layers 12 and 22 are examples of the “second active layer” and the “first active layer” in the present invention, respectively.

The n-type semiconductor layer 11 of the blue semiconductor laser element 10 has an n-type cladding layer 11a of Si-doped n-type Al_{0.07}Ga_{0.93}N having a thickness of about 2 μm formed on the upper surface of the n-type GaN substrate 1, an n-type carrier blocking layer 11b of Si-doped n-type Al_{0.16}Ga_{0.84}N having a thickness of about 5 nm formed on the n-type cladding layer 11a and an n-type light guide layer 11c of Si-doped n-type In_{0.02}Ga_{0.98}N having a thickness of about 100 nm formed on the n-type carrier blocking layer 11b. The n-type cladding layer 11a is an example of the “second cladding layer” in the present invention, and the n-type carrier blocking layer 11b is an example of the “second carrier blocking layer” in the present invention. The n-type light guide layer 11c is an example of the “second light guide layer” in the present invention.

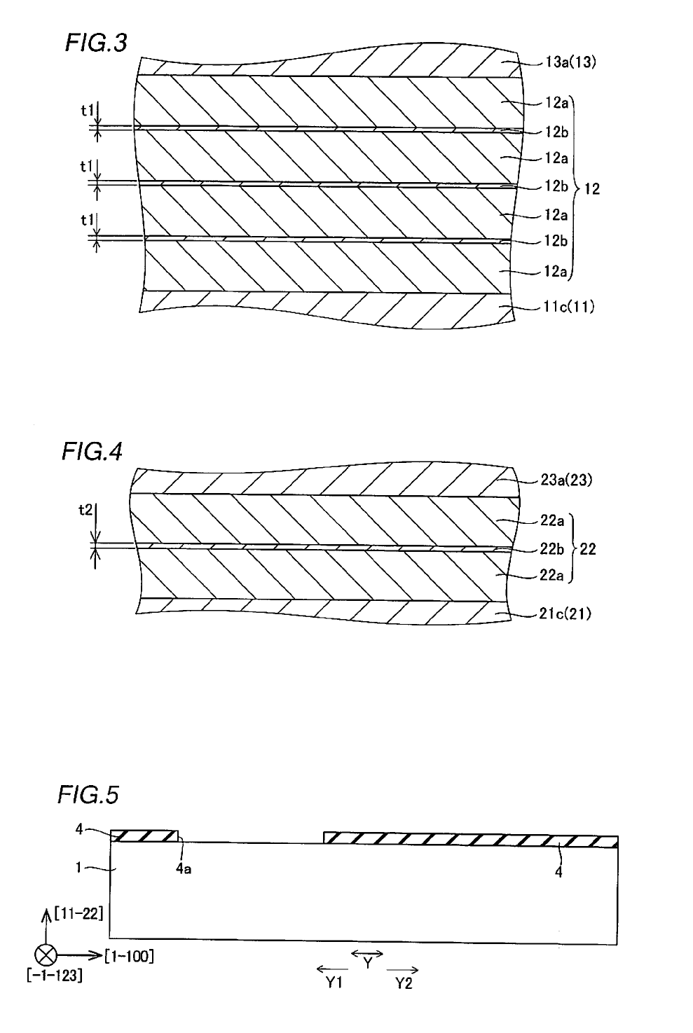

As shown in FIG. 3, the active layer 12 of the blue semiconductor laser element 10 is made of InGaN having a major surface of a (11-22) plane (see FIG. 2) identically to the n-type GaN substrate 1, and has an MQW structure. More specifically, the active layer 12 has an MQW structure obtained by alternately stacking four barrier layers 12a of undoped In_{0.02}Ga_{0.98}N each having a thickness of about 20 nm and three well layers 12b of undoped In_{0.20}Ga_{0.80}N each having a thickness t1 of about 3 nm on the upper surface of the n-type semiconductor layer 11. In other words, the well layers 12b of the active layer 12 of the blue semiconductor laser element 10 are made of InGaN having an In composition of about 20%. The in-plane lattice constant of the well layers 12b is larger than that of the n-type GaN substrate 1, and hence compressive strains are applied to the well layers 12b in the in-plane direction. The major surface of the active layer 12 is so of the (11-22) plane that a piezoelectric field in the active layer 12 can be reduced as compared with a case where the major surface of the active layer 12 is of a c-plane ((001) plane: see FIG. 2) which is a polar plane or another semipolar plane.

The blue semiconductor laser element 10 is so formed that the direction of polarization maximizing vibrator strength in the major surface thereof is a [1-100] direction perpendicular to an m-plane ((1-100) plane) which is a non-polar plane shown in FIG. 2.

As shown in FIG. 1, the p-type semiconductor layer 13 has a p-type light guide layer 13a of Mg-doped p-type In_{0.02}Ga_{0.98}N having a thickness of about 100 nm formed on the upper surface of the active layer 12, a p-type carrier blocking layer 13b of Mg-doped p-type Al_{0.16}Ga_{0.84}N having a thickness of about 20 nm formed on the p-type light guide layer 13a, a p-type cladding layer 13c of Mg-doped p-type Al_{0.07}Ga_{0.93}N having a thickness of about 700 nm formed on the p-type carrier blocking layer 13b and a p-type contact layer 13d of Mg-doped p-type In_{0.02}Ga_{0.98}N having a thickness of about 10 nm formed on the p-type cladding layer 13c. The p-type light guide layer 13a is an example of the “second light guide layer” in the present invention. The p-type carrier blocking layer 13b is an example of the “second carrier blocking layer” in the present invention, and the p-type cladding layer 13c is an example of the “second cladding layer” in the present invention.

The p-type cladding layer 13c and the p-type contact layer 13d constitute a striped ridge 13e formed on a substantially central portion of the blue semiconductor laser element 10 in a direction Y (directions Y1 and Y2). The ridge 13e constitutes the light guide. The ridge 13e is formed to extend along an extensional direction ([-1-123] direction) of the light guide projecting a [0001] direction on the (11-22) plane. The p-type cladding layer 13c has planar portions extending on both sides (in the direction Y) of the ridge 13e.

A current blocking layer 2 which is an insulating film is formed to cover the upper surfaces of the planar portions of the p-type cladding layer 13c, the side surfaces of the ridge 13e and the side surfaces of the re-type semiconductor layer 11, the active layer 12, the p-type light guide layer 13a, the p-type carrier blocking layer 13b and the p-type cladding layer 13c while exposing the upper surface of the ridge 13e. The current blocking layer 2 is made of SiO₂, and has a thickness of about 250 nm. The current blocking layer 2 is formed to further cover a prescribed region (region exposed from the blue semiconductor laser element 10 and the green semiconductor laser element 20) of the upper surface of the n-type GaN substrate 1, the upper surfaces of planar portions of a p-type cladding layer 23c, described later, of the green semiconductor laser element 20, the side surfaces of a ridge 23e described later and partial side surfaces of the n-type semiconductor layer 21, the active layer 22 and the p-type semiconductor layer 23 while exposing the upper surface of the ridge 23e. A p-side ohmic electrode 14 prepared by stacking a Pt layer having a thickness of about 5 nm, a Pd layer having a thickness of about 100 nm and an Au layer having a thickness of about 150 nm successively from the side closer to the p-type contact layer 13d is formed on the upper surface of the p-type contact layer 13d. A p-side pad electrode 15 prepared by stacking a Ti layer having a thickness of about 100 nm, a Pd layer having a thickness of about 100 nm and an Au layer having a thickness of about 3 μm successively from the side closer to the p-side ohmic electrode 14 is formed on a prescribed region (region located on the planar portions of the p-type cladding layer 13c and the side surfaces of the ridge 13e) of the current blocking layer 2 and the upper surface of the p-side ohmic electrode 14, to be electrically connected with the p-side ohmic electrode 14.

The green semiconductor laser element 20 has a structure similar to that of the blue semiconductor laser element 10, except for a well layer 22b, described later, of the active layer 22 described later. More specifically, the n-type semiconductor layer 21 of the green semiconductor laser element 20 has an n-type cladding layer 21a of Si-doped n-type Al_{0.10}Ga_{0.90}N having a thickness of about 2 μm formed on the upper surface of the n-type GaN substrate 1, an n-type carrier blocking layer 21b of Si-doped n-type Al_{0.20}Ga_{0.90}N having a thickness of about 5 nm formed on the n-type cladding layer 21a and an n-type light guide layer 21c of Si-doped n-type In_{0.05}Ga_{0.95}N having a thickness of about 100 nm formed on the n-type carrier blocking layer 21b. The n-type cladding layer 21a is an example of the “first cladding layer” in the present invention, and the n-type carrier blocking layer 21b is an example of the “first carrier blocking layer” in the present invention. The n-type light guide layer 21c is an example of the “first light guide layer” in the present invention.

As shown in FIG. 4, the active layer 22 of the green semiconductor laser element 20 is made of InGaN having a major surface of a (11-22) plane (see FIG. 2) identically to the n-type GaN substrate 1, and has an SQW structure. More specifically, the active layer 22 has an SQW structure obtained by alternately stacking two barrier layers 22a of undoped In_{0.02}Ga_{0.99}N each having a thickness of about 20 nm and the well layer 22b of undoped In_{0.33}Ga_{0.67}N having a thickness t2 of about 3.5 nm on the upper surface of the n-type semiconductor layer 21. In other words, the well layer 22b of the active layer 22 of the green semiconductor laser element 20 is made of InGaN having an In composition of about 33% larger than the In composition (about 20%) in the well layers 12b of the active layer 12 of the blue semiconductor laser element 10. Thus, the extensional direction of the light guide, described later, maximizing the gain of the green semiconductor laser element 20 and that of the light guide maximizing the gain of the blue semiconductor laser element 10 are rendered identical ([-1-123] directions) to each other.

The aforementioned directions of the light guides maximizing the gains of the green and blue semiconductor laser elements 20 and 10 are rendered identical ([-1-123] directions) to each other, on the basis of the fact that such a phenomenon has been found that, if the thickness of a well layer made of InGaN having a major surface of a (11-22) plane is less than about 3 nm when the In composition is at least about 30%, a main direction of polarization in the (11-22) plane rotates by 90° (rotates from a [1-100] direction to a [-1-123] direction). When the well layer 22b has an In composition of at least about 30%, therefore, the thickness t2 of the well layer 22b is preferably at least about 3 nm. When the thickness t2 of the well layer 22b of InGaN having the In composition of about 33% and the major surface of the (11-22) plane is set to about 3.5 nm (at least about 3 nm), the green semiconductor laser element 20 can be so formed that the extensional direction of the light guide maximizing the optical gain of the green semiconductor laser element 20 does not change by 90° with respect to the extensional direction of the light guide maximizing the optical gain of the blue semiconductor laser element 10. The in-plane lattice constant of the well layer 22b is larger than that of the n-type GaN substrate 1, and hence a compressive strain is applied to the well layer 22b in the in-plane direction. The compressive strain of the well layer 22b of the green semiconductor laser element 20 is larger than that of each well layer 12b of the blue semiconductor laser element 10. The major surface of the active layer 22 is so of the (11-22) plane that a piezoelectric field in the active layer 22 can be reduced as compared with a case where the major surface of the active layer 22 is of a c-plane ((001) plane: see FIG. 2) which is a polar plane or another semipolar plane.

The thickness t2 (about 3.5 nm) of the well layer 22b of the active layer 22 of the green semiconductor laser element 20 shown in FIG. 4 is rendered larger than the thickness t1 (about 3 nm) of each well layer 12b of the active layer 12 of the blue semiconductor laser element 10 show in FIG. 3.

As shown in FIG. 1, the p-type semiconductor layer 23 has a p-type light guide layer 23a of Mg-doped p-type In_{0.05}Ga_{0.95}N having a thickness of about 100 nm formed on the upper surface of the active layer 22, a p-type carrier blocking layer 23b of Mg-doped p-type Al_{0.20}Ga_{0.80}N having a thickness of about 20 nm formed on the p-type light guide layer 23a, the p-type cladding layer 23c of Mg-doped p-type Al_{0.10}Ga_{0.90}N having a thickness of about 700 nm formed on the p-type carrier blocking layer 23b and a p-type contact layer 23d of Mg-doped p-type In_{0.02}Ga_{0.98}N having a thickness of about 10 nm formed on the p-type cladding layer 23c. The p-type light guide layer 23a is an example of the “first light guide layer” in the present invention. The p-type carrier blocking layer 23b is an example of the “first carrier blocking layer” in the present invention, and the p-type cladding layer 23c is an example of the “first cladding layer” in the present invention.

The p-type cladding layer 23c and the p-type contact layer 23d constitute the striped ridge 23e formed on a substantially central portion of the green semiconductor laser element 20 in the direction Y. The ridge 23e constitutes the light guide. The ridge 23e is formed to extend along the extensional direction ([-1-123] direction) of the light guide projecting a [0001] direction on the (11-22) plane. The p-type cladding layer 23c has planar portions extending on both sides (in the direction Y) of the ridge 23e.

The Al compositions (about 10%) in the n- and p-type cladding layers 21a and 23c of the green semiconductor laser element 20 are rendered larger than the Al compositions (about 7%) in the n- and p-type cladding layers 11a and 13c of the blue semiconductor laser element 10. The Al compositions (about 20%) in the n- and p-type carrier blocking layers 21b and 23b of the green semiconductor laser element 20 are rendered larger than the Al compositions (about 16%) in the n- and p-type carrier blocking layers 11b and 13b of the blue semiconductor laser element 10. The In compositions (about 5%) in the n- and p-type light guide layers 21c and 23a of the green semiconductor laser element 20 are rendered larger than the In compositions (about 2%) in the n- and p-type light guide layers 11c and 13a of the blue semiconductor laser element 10. Thus, a green beam having a small refractive index can be confined between the cladding layers 21a and 23c and the carrier blocking layers 21b and 23b and the light guide layers 21c and 23a to an extent similar to that of a blue beam, whereby the green semiconductor laser element 20 can ensure light confinement to an extent similar to that of the blue semiconductor laser element 10.

The Al compositions in the n-type cladding layer 21a, the n-type carrier blocking layer 21b, the p-type carrier blocking layer 23b and the p-type cladding layer 23c of the green semiconductor laser element 20 are preferably larger than those in the n-type cladding layer 11a, the n-type carrier blocking layer 11b, the p-type carrier blocking layer 13b and the p-type cladding layer 13c of the blue semiconductor laser element 10, respectively. On the other hand, cracking and warpage resulting from different lattice constants of crystal lattices of AlGaN and the n-type GaN substrate 1 can be reduced by reducing the Al compositions in the blue and green semiconductor laser elements 10 and 20, although the light confinement functions are reduced in this case.

The In compositions in the n- and p-type light guide layers 21c and 23a of the green semiconductor laser element 20 are preferably larger than those in the n- and p-type light guide layers 11c and 13a of the blue semiconductor laser element 10.

A p-side ohmic electrode 24 similar to the p-side ohmic electrode 14 of the blue semiconductor laser element 10 is formed on the upper surface of the p-type contact layer 23d. A p-side pad electrode 25 similar to the p-side pad electrode 15 of the blue semiconductor laser element 10 is formed on a prescribed region (region located on the planar portions of the p-type cladding layer 23c and the side surfaces of the ridge 23e) of the current blocking layer 2 and the upper surface of the p-side ohmic electrode 24, to be separated from the p-side pad electrode 15 of the blue semiconductor laser element 10.

An n-side electrode 3 consisting of an Al layer having a thickness of about 10 nm, a Pt layer having a thickness of about 20 nm and an Au layer having a thickness of about 300 nm successively from the side closer to the n-type GaN substrate 1 is formed on the lower surface of the n-type GaN substrate 1.

The blue semiconductor laser element 10 and the green semiconductor laser element 20 are provided with cavity facets perpendicular to the extensional directions ([-1-123] directions) of the light guides. In other words, the blue and green semiconductor laser elements 10 and 20 are formed to have cavity facets consisting of the same surface orientations.

A process for manufacturing the semiconductor laser device 100 according to the first embodiment is now described with reference to FIGS. 1 to 7.

As shown in FIG. 5, a mask layer 4 of SiO₂ having an opening 4a of about 400 μm in width and having a thickness of about 500 nm is formed on the region of the upper surface of the n-type GaN substrate 1, having the major surface of the (11-22) plane (see FIG. 2), on the side of the [-1100] direction (direction Y1).

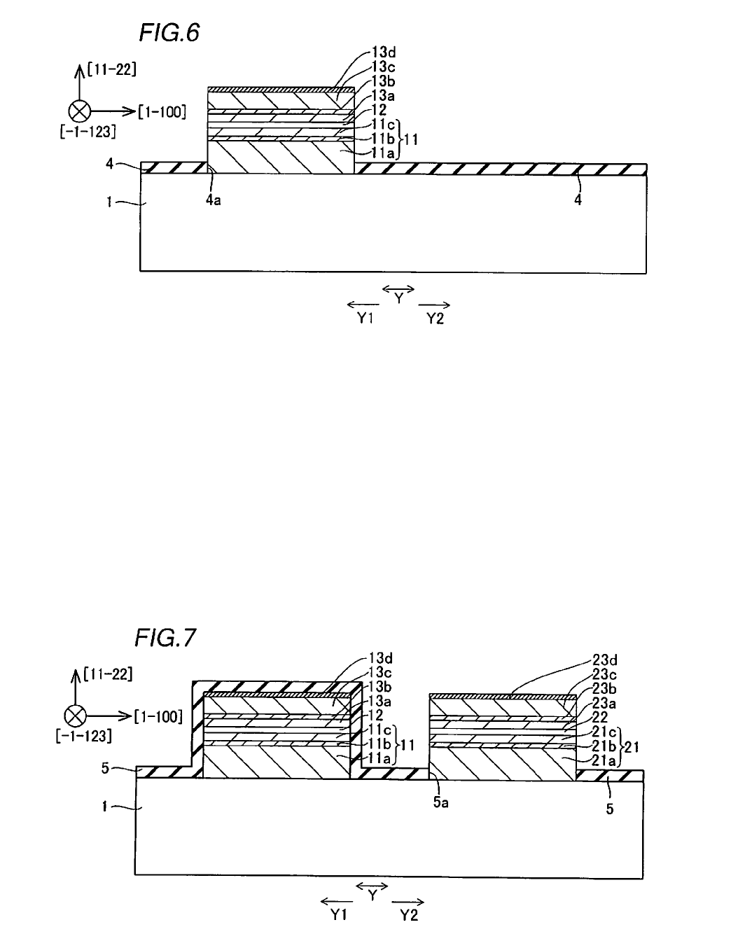

As shown in FIG. 6, the n-type semiconductor layer 11, the active layer 12 and the p-type semiconductor layer 13 not yet provided with the ridge 13e are selectively grown in this order by metal-organic chemical vapor deposition (MOCVD) on a portion of the upper surface of the n-type GaN substrate 1 exposed in the opening 4a of the mask layer 4.

Thereafter the mask layer 4 is removed. Then, a mask layer 5 of SiO₂ having a thickness of about 500 nm is formed on the upper surfaces of the n-type GaN substrate 1 and the p-type semiconductor layer 13 and the side surfaces of the n-type semiconductor layer 11, the active layer 12 and the p-type semiconductor layer 13.

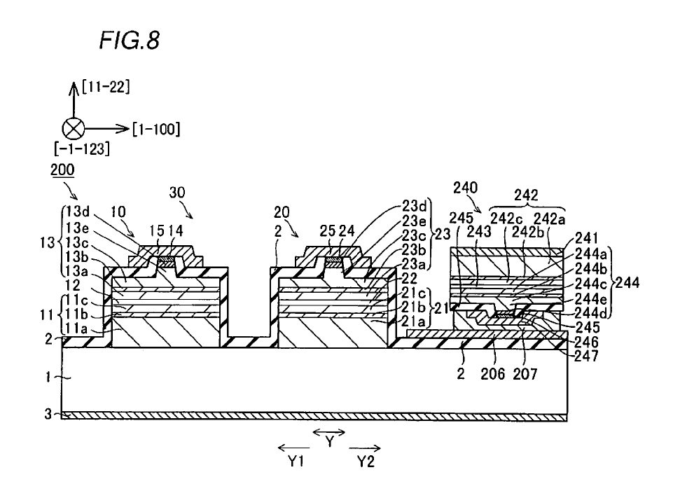

Then, a portion of the mask layer 5 located on the region of the upper surface of the n-type GaN substrate 1 on the side of the [1-100] direction (direction Y2) is removed thereby forming an opening 5a having a width of about 400 μm, as shown in FIG. 7. Thereafter the n-type semiconductor layer 21, the active layer 22 and the p-type semiconductor layer 23 not yet provided with the ridge 23e are selectively grown in this order by MOCVD on a portion of the upper surface of the n-type GaN substrate 1 exposed in the opening 5a from which the mask layer 5 is partially removed.

Thereafter the mask layer 5 is removed. Then, the ridges 13e and 23e are formed to extend along the extensional directions ([-1-123] directions) of the light guides. Consequently, the p-type semiconductor layers 13 and 23 are formed. Then, the current blocking layer 2 is formed. Then, portions of the current blocking layer 2 located on the upper surfaces of the p-type contact layers 13d and 23d are removed, to expose the p-type contact layers 13d and 23d. Thereafter the p-side ohmic electrodes 14 and 24 are formed on the upper surfaces of the p-type contact layers 13d and 23d by vacuum evaporation, respectively, and the p-side pad electrodes 15 and 25 are thereafter formed. The green semiconductor laser element 20 is formed on the surface of the n-type GaN substrate 1 identical to that provided with the blue semiconductor laser element 10 after the formation of the blue semiconductor laser element 10, so that the active layer 22, easily deteriorated by heat due to the large In composition, of the green semiconductor laser element 20 is not influenced by heat for forming the blue semiconductor laser element 10.

Thereafter the lower surface of the n-type GaN substrate 1 is polished so that the thickness of the n-type GaN substrate 1 is about 100 μm. Then, the n-side electrode 3 is formed on the lower surface of the n-type GaN substrate 1 by vacuum evaporation. Thus, the monolithic blue/green double-wavelength semiconductor laser element portion 30 is formed in a wafer state. Thereafter the cavity facets perpendicular to the extensional directions ([-1-123] directions) of the light guides are formed on prescribed positions by etching, and the wafer is divided. Thus, the individual monolithic blue/green double-wavelength semiconductor laser element portion 30 constituting the semiconductor laser device 100 is formed as shown in FIG. 1. The cavity facets may alternatively be formed by cleaving the prescribed positions of the wafer.

According to the first embodiment, as hereinabove described, the well layer 22b of the active layer 22, having the major surface of the (11-22) plane, of the green semiconductor laser element 20 is formed to have the thickness of about 3.5 nm, whereby the extensional directions ([-1-123] directions) of the light guides maximizing the optical gains of the blue and green semiconductor laser elements 10 and 20 can be matched with each other.

According to the first embodiment, the In composition in the well layer 22b is set to about 30% and the thickness of the well layer 22b is set to about 3 nm, whereby the extensional directions ([-1-123] directions) of the light guides maximizing the optical gains of the blue and green semiconductor laser elements 10 and 20 can be matched with each other.

According to the first embodiment, the well layer 22b of the active layer 22 of the green semiconductor laser element 20 is made of InGaN having the In composition larger than that in each well layer 12b of the active layer 12 of the blue semiconductor laser element 10, whereby the extensional directions ([-1-123] directions) of the light guides maximizing the optical gains of the blue and green semiconductor laser elements 10 and 20 can be matched with each other.

According to the first embodiment, the thickness t2 (about 3.5 nm) of the well layer 22b is rendered larger than the thickness t1 (about 3 nm) of each well layer 12b, whereby the active layer 12 of the blue semiconductor laser element 10 can be prevented from formation of misfit dislocations resulting from different lattice constants of the crystal lattices of the well layers 12b each having a large In composition and underlayers (barrier layers 12a), each having a small In composition, on which the well layers 12b are grown.

According to the first embodiment, the (11-22) plane inclined by about 58° is employed as the semipolar plane, whereby the extensional directions of the light guides maximizing the optical gains of the green and blue semiconductor laser elements 20 and 10 can be more reliably matched with each other. Further, the (11-22) plane has a smaller piezoelectric field as compared with other semipolar planes, whereby reduction in the luminous efficiencies of the green and blue semiconductor laser elements 20 and 10 can be further suppressed.

According to the first embodiment, the active layer 12 of the blue semiconductor laser element 10 is made of InGaN having the major surface of the (11-22) plane identically to the n-type GaN substrate 1 while the active layer 22 of the green semiconductor laser element 20 is also made of InGaN having the major surface of the (11-22) plane identically to the n-type GaN substrate 1, whereby the green and blue semiconductor laser elements 20 and 10 including the active layers 22 and 12 of InGaN having the major surfaces of the (11-22) planes can be easily formed by simply growing semiconductor layers on the n-type GaN substrate 1 of GaN having the major surface of the (11-22) plane similarly to the active layers 22 and 12 of the green and blue semiconductor laser elements 20 and 10.

According to the first embodiment, the blue and green semiconductor laser elements 10 and 20 are provided with the light guides extending in the directions ([-1-123] directions) projecting the [0001] directions on the (11-22) planes, whereby the optical gains of the blue and green semiconductor laser elements 10 and 20 can be maximized, while the blue and green beams of the blue and green semiconductor laser elements 10 and 20 can be emitted from common cavity facets.

According to the first embodiment, the In compositions (about 5%) in the n- and p-type light guide layers 21c and 23a of the green semiconductor laser element 20 are rendered larger than the In compositions (about 2%) in the n- and p-type light guide layers 11c and 13a of the blue semiconductor laser element 10 so that the n- and p-type light guide layers 21c and 23a can more confine light in the active layers (12 and 22) than the n- and p-type light guide layers 11c and 13a, whereby the green beam of the green semiconductor laser element 20 can be more confined in the active layer 22. Thus, the green semiconductor laser element 20 inferior in luminous efficiency as compared with the blue semiconductor laser element 10 can ensure light confinement to an extent similar to that of the blue semiconductor laser element 10.

According to the first embodiment, the Al compositions (about 20%) in the n- and p-type carrier blocking layers 21b and 23b of the green semiconductor laser element 20 are rendered larger than the Al compositions (about 16%) in the n- and p-type carrier blocking layers 11b and 13b of the blue semiconductor laser element 10 so that the n- and p-type carrier blocking layers 21b and 23b can more confine light in the active layers (12 and 22) than the n- and p-type carrier blocking layers 11b and 13b, whereby the green beam of the green semiconductor laser element 20 can be more confined in the active layer 22. Thus, the green semiconductor laser element 20 inferior in luminous efficiency as compared with the blue semiconductor laser element 10 can ensure light confinement to an extent similar to that of the blue semiconductor laser element 10.

According to the first embodiment, the Al compositions (about 10%) in the n- and p-type cladding layers 21a and 23c of the green semiconductor laser element 20 are rendered larger than the Al compositions (about 7%) in the n- and p-type cladding layers 11a and 13c of the blue semiconductor laser element 10 so that the n- and p-type cladding layers 21a and 23c can more confine light in the active layers (12 and 22) than the n- and p-type cladding layers 11a and 13c, whereby the green beam of the green semiconductor laser element 20 can be more confined in the active layer 22. Thus, the green semiconductor laser element 20 inferior in luminous efficiency as compared with the blue semiconductor laser element 10 can ensure light confinement to an extent similar to that of the blue semiconductor laser element 10.

### Second Embodiment

A semiconductor laser device 200 according to a second embodiment of the present invention is now described with reference to FIGS. 8 to 11. In the semiconductor laser device 200 according to the second embodiment, a red semiconductor laser element 240 is bonded onto an n-type GaN substrate 1 provided with a monolithic blue/green double-wavelength semiconductor laser element portion 30, dissimilarly to the aforementioned first embodiment. Projectors 250 and 260 each including the semiconductor laser device 200 are also described.

First, the structure of the semiconductor laser device 200 according to the second embodiment of the present invention is described with reference to FIG. 8.

In the semiconductor laser device 200 according to the second embodiment of the present invention, the red semiconductor laser element 240 having an oscillation wavelength of about 640 nm is bonded onto the upper surface of the n-type GaN substrate 1 on the side of a [1-100] direction (direction Y2), not provided with a blue semiconductor laser element 10 and a green semiconductor laser element 20, in a junction-down manner to direct a p-n junction portion downward, as shown in FIG. 8. The red semiconductor laser element 240 has an oscillation wavelength in the range of about 610 nm to about 750 nm. More specifically, a p-side electrode 206 is formed on the upper surface of a current blocking layer 2, formed on the n-type GaN substrate 1, on the side of the direction Y2 at a prescribed interval from the green semiconductor laser element 20. The p-side electrode 206 is provided to be wire-bondable with a wire (not shown). The red semiconductor laser element 240 is bonded onto the upper surface of the p-side electrode 206 with a fusion layer 207 made of conductive solder or the like.

The red semiconductor laser element 240 has a structure obtained by stacking an n-type semiconductor layer 242, an active layer 243 and a p-type semiconductor layer 244 in this order on the lower surface of an n-side electrode 241 formed by stacking an AuGe layer, an Ni layer and an Au layer in this order. The n-type semiconductor layer 242 has a structure obtained by stacking an n-type cladding layer 242a of Si-doped n-type AlGaInP, an n-type carrier blocking layer 242b of undoped AlGaInP and an n-type light guide layer 242c of undoped AlGaInP in this order on the lower surface of the n-side electrode 241.

The active layer 243 of the red semiconductor laser element 240 has an MQW structure obtained by alternately stacking two barrier layers of undoped AlGaInP and three well layers of undoped InGaP on the lower surface of the n-type semiconductor layer 242. The active layer 243 may alternatively have a single-layer structure or an SQW structure.

The p-type semiconductor layer 244 has a structure obtained by stacking a p-type light guide layer 244a of undoped AlGaInP, a p-type carrier blocking layer 244b of undoped AlGaInP, a p-type cladding layer 244c of Zn-doped p-type AlGaInP and a p-type contact layer 244d consisting of a multilayer structure of a Zn-doped p-type GaInP layer and a Zn-doped p-type GaAs layer in this order on the lower surface of the active layer 243. The p-type cladding layer 244c and the p-type contact layer 244d constitute a striped ridge 244e formed on a substantially central portion of the red semiconductor laser element 240 in a direction Y (directions Y1 and Y2), while the p-type cladding layer 244c has planar portions extending on both sides (in the direction Y) of the ridge 244e. The ridge 244e constitutes a light guide.

A current blocking layer 245 which is an insulating film is formed to cover the lower surfaces of the planar portions of the p-type cladding layer 244c and the side surfaces of the ridge 244e while exposing the lower surface of the ridge 244e. A p-side ohmic electrode 246 prepared by stacking a Cr layer and an Au layer in this order is formed on the lower surface of the p-type contact layer 244d. A p-side electrode 247 of Au or the like is formed on a prescribed region of the current blocking layer 245 and the lower surface of the p-side ohmic electrode 246, to be electrically connected with the p-side ohmic electrode 246. Prescribed regions of the p-side electrode 247 and the current blocking layer 245 are bonded to the p-side electrode 206 through the fusion layer 207. The remaining structure of the semiconductor laser device 200 according to the second embodiment is similar to that of the semiconductor laser device 100 according to the aforementioned first embodiment.

The projectors 250 and 260 each including the semiconductor laser device 200 according to the second embodiment of the present invention are described with reference to FIGS. 8 to 11.

First, the projector 250 turning on the semiconductor laser elements 10, 20 and 240 in a time-series manner is described with reference to FIGS. 8 to 10.

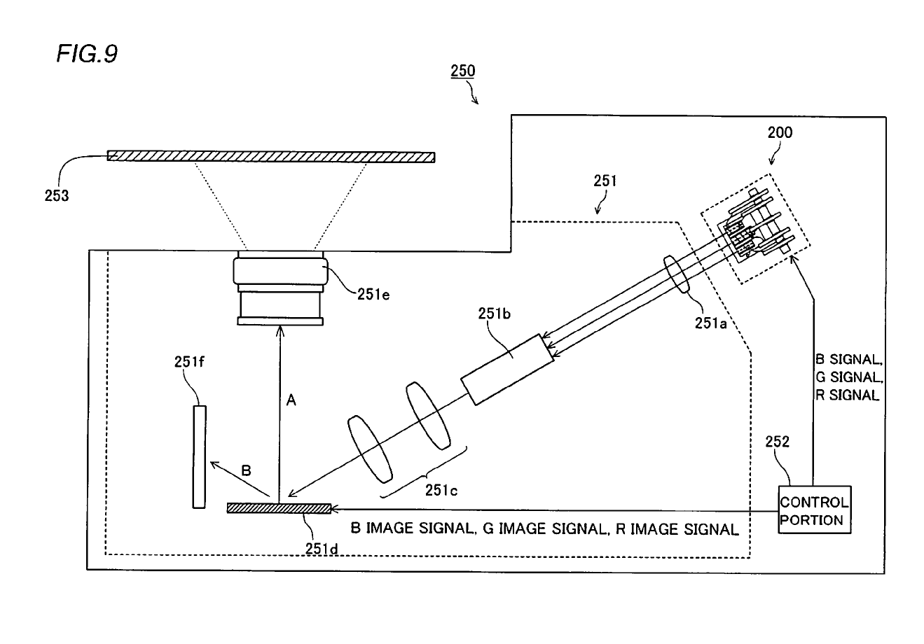

The projector 250 according to the second embodiment of the present invention is provided with the semiconductor laser device 200 including the blue semiconductor laser element 10 (see FIG. 8), the green semiconductor laser element 20 (see FIG. 8) and the red semiconductor laser element 240 (see FIG. 8), an optical system 251 consisting of a plurality of optical components and a control portion 252 controlling the semiconductor laser device 200 and the optical system 251, as shown in FIG. 9. Thus, the projector 250 is so formed that beams emitted from the semiconductor laser device 200 are modulated by the optical system 251 and thereafter projected on a screen 253 or the like.

In the optical system 251, the beams emitted from the semiconductor laser device 200 are converted to parallel beams by a lens 251a, and thereafter introduced into a light pipe 251b.

The light pipe 251b has a specular inner surface, and the beams are repeatedly reflected by the inner surface of the light pipe 251b to travel in the light pipe 251b. At this time, intensity distributions of the beams of respective colors emitted from the light pipe 251b are uniformized due to multiple reflection in the light pipe 251b. The beams emitted from the light pipe 251b are introduced into a digital micromirror device (DMD) 251d through a relay optical system 251c.

The DMD 251d consists of a group of small mirrors arranged in the form of a matrix. The DMD 251d has a function of expressing (modulating) the gradation of each pixel by switching the direction of reflection of light on each pixel position between a first direction A toward a projection lens 251e and a second direction B deviating from the projection lens 251e. Light (ON-light) incident upon each pixel position and reflected in the first direction A is introduced into the projection lens 251e and projected on a projected surface (screen 253). On the other hand, light (OFF-light) reflected by the DMD 251d in the second direction B is not introduced into the projection lens 251e but absorbed by a light absorber 251f.

In the projector 250, the control portion 252 is formed to supply a pulse voltage to the semiconductor laser device 200, thereby dividing the blue semiconductor laser element 10, the green semiconductor laser element 20 and the red semiconductor laser element 240 of the semiconductor laser device 200 in a time-series manner and cyclically driving the same one by one. Further, the control portion 252 is so formed that the DMD 251d of the optical system 251 modulates the gradations between the respective pixels in synchronization with the driving of the blue semiconductor laser element 10, the green semiconductor laser element 20 and the red semiconductor laser element 240.

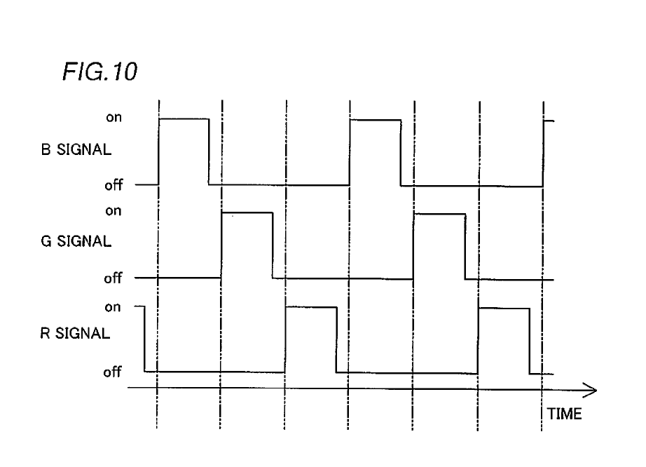

More specifically, a B signal related to the driving of the blue semiconductor laser element 10, a G signal related to the driving of the green semiconductor laser element 20 and an R signal related to the driving of the red semiconductor laser element 240 are divided in a time-series manner not to overlap with each other and supplied to the semiconductor laser device 200 by the control portion 252, as shown in FIG. 10. In synchronization with the B, G and R signals, the control portion 252 outputs a B image signal, a G image signal and an R image signal to the DMD 251d.

Thus, the blue semiconductor laser element 10 emits a blue beam on the basis of the B signal, while the DMD 251d modulates the blue beam at this timing on the basis of the B image signal. Further, the green semiconductor laser element 20 emits a green beam on the basis of the G signal output subsequently to the B signal, and the DMD 251d modulates the green beam at this timing on the basis of the G image signal. In addition, the red semiconductor laser element 240 emits a red beam on the basis of the R signal output subsequently to the G signal, and the DMD 251d modulates the red beam at this timing on the basis of the R image signal. Thereafter the blue semiconductor laser element 10 emits the blue beam on the basis of the B signal output subsequently to the R signal, and the DMD 251d modulates the blue beam again at this timing on the basis of the B image signal. The aforementioned operations are so repeated that an image formed by application of the laser beams based on the B, G and R image signals is projected on the projected surface (screen 253). The projector 250 cyclically turning on the semiconductor laser elements 10, 20 and 240 of the semiconductor laser device 200 according to the second embodiment of the present invention in a time-series manner is constituted in the aforementioned manner.

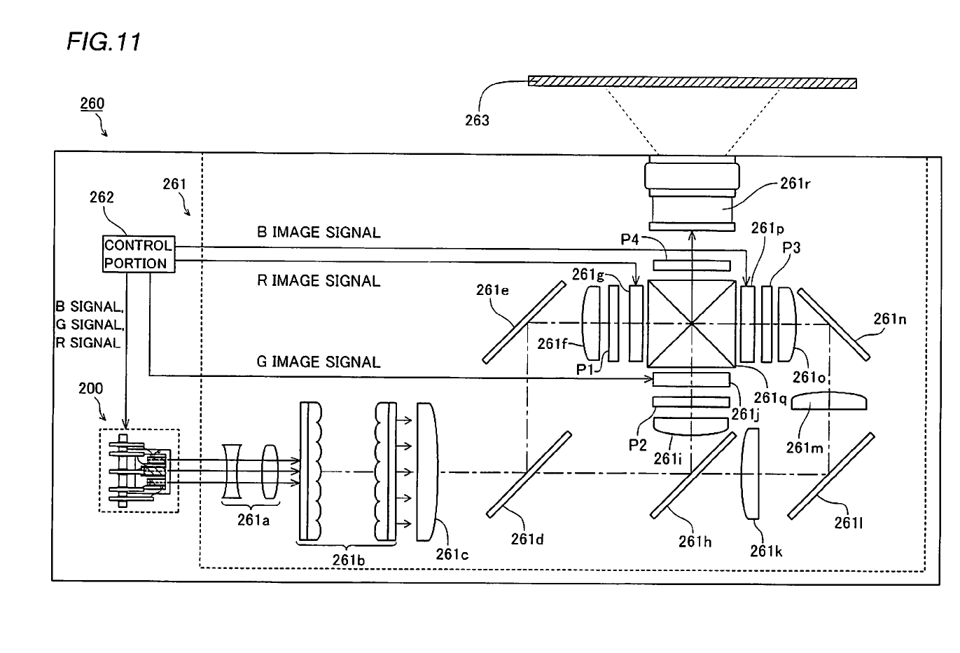

The projector 260 substantially simultaneously turning on the semiconductor laser elements 10, 20 and 240 is now described with reference to FIGS. 8 and 11.

The projector 260 according to the second embodiment of the present invention is provided with the semiconductor laser device 200 including the blue semiconductor laser element 10 (see FIG. 8), the green semiconductor laser element 20 (see FIG. 8) and the red semiconductor laser element 240 (see FIG. 8), an optical system 261 consisting of a plurality of optical components and a control portion 262 controlling the semiconductor laser device 200 and the optical system 261, as shown in FIG. 11. Thus, the projector 260 is so formed that laser beams emitted from the semiconductor laser device 200 are modulated by the optical system 261 and thereafter projected on an external screen 263 or the like.

In the optical system 261, the laser beams emitted from the semiconductor laser device 200 are converted to parallel beams having prescribed beam diameters by a dispersion angle control lens 261a consisting of a concave lens and a convex lens, and thereafter introduced into a fly-eye integrator 261b. The fly-eye integrator 261b is so formed that two fly-eye lenses consisting of fly-eye lens groups face each other, and provides a lens function to the beams introduced from the dispersion angle control lens 261a so that light quantity distributions in incidence upon liquid crystal panels 261g, 261j and 261p are uniform. In other words, the beams transmitted through the fly-eye integrator 261b are so adjusted that the same can be incident upon the liquid crystal panels 261g, 261j and 261p with spreads of aspect ratios (16:9, for example) corresponding to the sizes of the liquid crystal panels 261g, 261j and 261p.

The beams transmitted through the fly-eye integrator 261b are condensed by a condenser lens 261c. In the beams transmitted through the condenser lens 261c, only the red beam is reflected by a dichroic mirror 261d, while the green and blue beams are transmitted through the dichroic mirror 261d.

The red beam is parallelized by a lens 261f through a mirror 261e, and thereafter incident upon the liquid crystal panel 261g. The liquid crystal panel 261g is driven in response to a red driving signal (R image signal), thereby modulating the red beam. The red beam transmitted through the lens 261f is incident upon the liquid crystal panel 261g through an incidence-side polarizing plate P1.

In the beams transmitted through the dichroic mirror 261d, only the green beam is reflected by a dichroic mirror 261h, while the blue beam is transmitted through the dichroic mirror 261h.

The green beam is parallelized by a lens 261i, and thereafter incident upon the liquid crystal panel 261j. The liquid crystal panel 261j is driven in response to a green driving signal (G image signal), thereby modulating the green beam. The green beam transmitted through the lens 261i is incident upon the liquid crystal panel 261j through an incidence-side polarizing plate P2.

The blue beam transmitted through the dichroic mirror 261h passes through a lens 261k, a mirror 261l, a lens 261m and a mirror 261n, is parallelized by a lens 261o, and thereafter incident upon the liquid crystal panel 261p. The liquid crystal panel 261p is driven in response to a blue driving signal (B image signal), thereby modulating the blue beam. The blue beam transmitted through the lens 2610 is incident upon the liquid crystal panel 261p through an incidence-side polarizing plate P3.

Thereafter the red, green and blue beams modulated by the liquid crystal panels 261g, 261j and 261p are synthesized by a dichroic prism 261q, and thereafter introduced into a projection lens 261r through an emission-side polarizing plate P4. The projection lens 261r stores a lens group for imaging projected light on a projected surface (screen 263) and an actuator for adjusting the zoom and the focus of the projected image by partially displacing the lens group in an optical axis direction.

In the projector 260, the control portion 262 supplies stationary voltages as a B signal related to driving of the blue semiconductor laser element 10, a G signal related to driving of the green semiconductor laser element 20 and an R signal related to driving of the red semiconductor laser element 240 to the semiconductor laser elements 10, 20 and 240 of the semiconductor laser device 200, respectively. Thus, the blue semiconductor laser element 10, the green semiconductor laser element 20 and the red semiconductor laser element 240 of the semiconductor laser device 200 are substantially simultaneously oscillated. The control portion 262 is formed to control the intensities of the beams emitted from the blue semiconductor laser element 10, the green semiconductor laser element 20 and the red semiconductor laser element 240 of the semiconductor laser device 200, thereby controlling the hue, brightness etc. of pixels projected on the screen 263. Thus, the control portion 262 projects a desired image on the screen 263. The projector 260 substantially simultaneously turning on the semiconductor laser elements 10, 20 and 240 of the semiconductor laser device 200 according to the second embodiment of the present invention is constituted in the aforementioned manner.

According to the second embodiment, as hereinabove described, the RBG triple-wavelength semiconductor laser device 200 including the blue/green double-wavelength semiconductor laser element portion 30 including the blue and green semiconductor laser elements 10 and 20 matching extensional directions ([-1-123] directions) of light guides maximizing optical gains with each other and the red semiconductor laser element 240 can be obtained due to the provision of the red semiconductor laser element 240 bonded onto the n-type GaN substrate 1.

According to the second embodiment, the red semiconductor laser element 240 is bonded onto the upper surface of the n-type GaN substrate 1 in the direction Y2 in the junction-down manner to direct the p-n junction portion downward so that heat generated in the active layer 243 of the red semiconductor laser element 240 can be radiated on the n-type GaN substrate 1, whereby the RGB triple-wavelength semiconductor laser device 200 including the red semiconductor laser element 240 having a higher luminous efficiency can be prepared.

According to the second embodiment, the projector 250 is so formed that the control portion 252 supplies the pulse voltage to the semiconductor laser device 200 thereby dividing the blue semiconductor laser element 10, the green semiconductor laser element 20 and the red semiconductor laser element 240 of the semiconductor laser device 200 in a time-series manner and cyclically driving the same one by one. According to this structure, the extensional directions ([-1-123] directions) of the light guides maximizing the optical gains of the blue and green semiconductor laser elements 10 and 20 can be matched with each other also when it is difficult to ensure brightness necessary in the blue, green and red semiconductor laser elements 10, 20 and 240 of the semiconductor laser device 200 divided in a time-series manner and cyclically driven one by one. Thus, the efficiency of the green semiconductor laser element 20 having a low luminous efficiency can be increased, whereby necessary brightness can be more reliably ensured in the semiconductor laser device 200.

According to the second embodiment, the projector 260 is so formed that the control portion 262 supplies the stationary voltages to the semiconductor laser device 200 thereby substantially simultaneously oscillating the blue semiconductor laser element 10, the green semiconductor laser element 20 and the red semiconductor laser element 240 of the semiconductor laser device 200. According to this structure, the extensional directions ([-1-123] directions) of the light guides maximizing the optical gains of the blue and green semiconductor laser elements 10 and 20 can be matched with each other also when power consumption is increased in the semiconductor laser device 200 whose semiconductor laser elements 10, 20 and 240 are substantially simultaneously oscillated. Thus, the efficiency of the green semiconductor laser element 20 having a low luminous efficiency can be increased, whereby the semiconductor laser device 200 can be inhibited from increase in the power consumption.

According to the second embodiment, the projector 250 is provided with the semiconductor laser device 200 and the optical system 251 while the projector 260 is provided with the semiconductor laser device 200 and the optical system 261, whereby a desired image can be displayed by employing the semiconductor laser device 200 substantially matching the extensional directions ([-1-123] directions) of the light guides maximizing the optical gains of the blue and green semiconductor laser elements 10 and 20 with each other and modulating the beams with the optical system 251 or 261. The remaining effects of the second embodiment are similar to those of the aforementioned first embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the well layer of the active layer of the green semiconductor laser element is formed to have the thickness of about 3.5 nm in each of the aforementioned first and second embodiments, the present invention is not restricted to this. According to the present invention, the well layer of the active layer of the green semiconductor laser element may simply be formed to have a thickness of at least about 3 nm. The well layer of the active layer of the green semiconductor laser element preferably has a thickness of not more than about 10 nm.

While each of the plurality of well layers constituting the MQW structure of the blue semiconductor laser element is formed to have the thickness of about 3 nm in each of the aforementioned first and second embodiments, the present invention is not restricted to this. According to the present invention, the thickness of each well layer of the active layer of the blue semiconductor laser element is not particularly restricted. The thickness of each well layer of the active layer of the blue semiconductor laser element is preferably smaller than the thickness of the well layer of the active layer of the green semiconductor laser element.

While the (11-22) planes which are semipolar planes are employed as the surface orientations of the major surfaces of the active layers of the blue and green semiconductor laser elements in each of the aforementioned first and second embodiments, the present invention is not restricted to this. According to the present invention, other semipolar planes such as (11-2x) planes (x=2, 3, 4, 5, 6, 8, 10, −2, −3, −4, −5, −6, −8 or −10) or (1-10y) planes (y=1, 2, 3, 4, 5, 6, −1, −2, −3, −4, −5 or −6) may alternatively be employed as the surface orientations of the first and second major surfaces of the active layers of the blue and green semiconductor laser elements. In this case, the thicknesses of and the In compositions in the active layers of the blue and green semiconductor laser elements are properly changed. The semipolar planes are preferably inclined with respect to (0001) planes or (000-1) planes by at least about 10° and not more than about 70°.

While the active layers of the blue and green semiconductor laser elements are formed to have the MQW and SQW structures, respectively, in each of the aforementioned first and second embodiments, the present invention is not restricted to this. According to the present invention, the active layers of the blue and green semiconductor laser elements may alternatively be formed to have SQW and MQW structures, respectively.

While the well layer of the active layer of the green semiconductor laser element is made of InGaN having the In composition of about 33% in each of the aforementioned first and second embodiments, the present invention is not restricted to this. According to the present invention, the composition of the well layer of the active layer of the green semiconductor laser element is not particularly restricted. The well layer of the active layer of the green semiconductor laser element is preferably made of InGaN having an In composition of at least about 30%.

While the active layers of InGaN having the major surfaces of the (11-22) planes are formed on the upper surface of the n-type GaN substrate in each of the aforementioned first and second embodiments, the present invention is not restricted to this. According to the present invention, the active layers of InGaN having the major surfaces of the (11-22) planes may alternatively be formed on the upper surface of a substrate made of Al₂O₃, SiC, LiAlO₂ or LiGaO₂, for example.

While the well layers of the blue and green semiconductor laser elements are made of InGaN in each of the aforementioned first and second embodiments, the present invention is not restricted to this. According to the present invention, the well layers of the blue and green semiconductor laser elements may alternatively be made of nitride-based semiconductors such as AlInGaN or InAlN containing In, or nitride-based semiconductors such as AlGaN containing no In. In this case, the thickness and the composition of the active layer of the blue semiconductor laser element are properly changed.

While the barrier layers of the blue and green semiconductor laser elements are made of InGaN in each of the aforementioned first and second embodiments, the present invention is not restricted to this. According to the present invention, the barrier layers of the blue and green semiconductor laser elements may alternatively be made of nitride-based semiconductors such as GaN, AlGaN or AlGaInN having a larger band gap than the well layers.

While the active layers of InGaN having the major surfaces of the (11-22) planes are formed on the n-type GaN substrate having the major surface of the (11-22) plane in each of the aforementioned first and second embodiments, the present invention is not restricted to this. According to the present invention, a sapphire substrate having a major surface of an r-plane ((1-102) plane) prepared by previously growing a nitride-based semiconductor (InGaN, for example) having a major surface of a (11-22) plane, a (1-103) plane or a (1-126) plane may alternatively be employed.

While the active layers of InGaN are formed on the n-type GaN substrate in each of the aforementioned first and second embodiments, the present invention is not restricted to this. According to the present invention, the active layers of InGaN may alternatively be formed on an AlₓGa₁₋ₓN substrate. Spreads of intensity distributions of the beams in a vertical/transverse mode can be suppressed by increasing the Al composition. Thus, emission of light from the AlₓGa₁₋ₓN substrate can be suppressed, and hence each laser element can be inhibited from emitting a plurality of beams of the vertical/transverse mode. Further alternatively, the active layers of InGaN may be formed on an InₓGa_{1-y}N substrate. Thus, strains in the active layers can be reduced by adjusting the In composition in the InₓGa_{1-y}N substrate. In this case, the thicknesses of and the In compositions in the active layers of the blue and green semiconductor laser elements are properly changed.

While the semiconductor layers constituting the blue and green semiconductor laser elements are formed by selectively growing the same through the mask layers formed on the n-type GaN substrate in each of the aforementioned first and second embodiments, the present invention is not restricted to this. According to the present invention, the blue semiconductor laser element may alternatively be formed on the overall surface of the n-type GaN substrate and thereafter partly etched to partly expose the n-type GaN substrate, so that the green semiconductor laser element is formed on the exposed portion.

While the semiconductor laser elements including ridge guided light guides are formed by forming the p-type cladding layers having the ridges on the planar active layers and forming the current blocking layers which are insulating films on the side surfaces of the ridges in each of the aforementioned first and second embodiments, the present invention is not restricted to this. According to the present invention, semiconductor laser elements including ridge guided light guides having current blocking layers of semiconductors, semiconductor laser elements including light guides of embedded heterostructures or semiconductor laser elements including gain guided light guides prepared by forming current blocking layers having striped openings on planar p-type cladding layers may alternatively be formed.

While the red semiconductor laser element is bonded onto the upper surface of the n-type GaN substrate in the junction-down manner to direct the p-n junction portion downward in the aforementioned second embodiment, the present invention is not restricted to this. According to the present invention, the red semiconductor laser element may alternatively be bonded onto the upper surface of the n-type GaN substrate in a junction-up manner to direct the p-n junction portion upward.

While the n-type GaN substrate and the active layers of the blue and green semiconductor laser elements are formed to have the major surfaces of the same semipolar planes ((11-22) planes) in each of the aforementioned first and second embodiments, the present invention is not restricted to this. According to the present invention, the n-type GaN substrate and the active layers of the blue and green semiconductor laser elements may alternatively be formed to have major surfaces of different surface orientations.

While the n-type cladding layers, the n-type carrier blocking layers, the p-type carrier blocking layers and the p-type cladding layers of the blue and green semiconductor laser elements are made of AlGaN in each of the aforementioned first and second embodiments, the present invention is not restricted to this. According to the present invention, the n-type cladding layers, the n-type carrier blocking layers, the p-type carrier blocking layers and the p-type cladding layers of the blue and green semiconductor laser elements may alternatively be made of AlInGaN. In this case, the Al compositions in the n-type cladding layer, the n-type carrier blocking layer, the p-type carrier blocking layer and the p-type cladding layer of the green semiconductor laser element are preferably larger than those in the n-type cladding layer, the n-type carrier blocking layer, the p-type carrier blocking layer and the p-type cladding layer of the blue semiconductor laser element, respectively.

While the n- and p-type light guide layers of the blue and green semiconductor laser elements are made of InGaN in each of the aforementioned first and second embodiments, the present invention is not restricted to this. According to the present invention, the n- and p-type light guide layers of the blue and green semiconductor laser elements may alternatively be made of AlInGaN. In this case, the In compositions in the n- and p-type light guide layers of the green semiconductor laser element are preferably larger than those in the n- and p-type light guide layers of the blue semiconductor laser element, respectively.

While the In compositions in the n- and p-type light guide layers of the green semiconductor laser element are rendered larger than those in the n- and p-type light guide layers of the blue semiconductor laser element, respectively, in each of the aforementioned first and second embodiments, the present invention is not restricted to this. According to the present invention, the In compositions in the n- and p-type light guide layers of the green semiconductor laser element may alternatively be rendered smaller than those in the n- and p-type light guide layers of the blue semiconductor laser element, respectively.

While the Al compositions in the n- and p-type carrier blocking layers of the green semiconductor laser element are rendered larger than those in the n- and p-type carrier blocking layers of the blue semiconductor laser element in each of the aforementioned first and second embodiments, the present invention is not restricted to this. According to the present invention, the Al compositions in the n- and p-type carrier blocking layers of the green semiconductor laser element may alternatively be rendered smaller than those in the n- and p-type carrier blocking layers of the blue semiconductor laser element, respectively.

While the Al compositions in the n- and p-type cladding layers of the green semiconductor laser element are rendered larger than those in the n- and p-type cladding layers of the blue semiconductor laser element in each of the aforementioned first and second embodiments, the present invention is not restricted to this. According to the present invention, the Al compositions in the n- and p-type cladding layers of the green semiconductor laser element may alternatively be rendered smaller than those in the n- and p-type cladding layers of the blue semiconductor laser element, respectively.

While the blue semiconductor laser element, the green semiconductor laser element and the red semiconductor laser element are arranged successively from the side of the direction Y1 in the aforementioned second embodiment, the present invention is not restricted to this. According to the present invention, the arrangement of the blue semiconductor laser element, the green semiconductor laser element and the red semiconductor laser element is not particularly restricted. The red semiconductor laser element may alternatively be bonded onto the upper portion of the blue or green semiconductor laser element.

While the semiconductor laser device is constituted of one blue semiconductor laser element and one green semiconductor laser element (as well as one red semiconductor laser element) in each of the aforementioned first and second embodiments, the present invention is not restricted to this. According to the present invention, the semiconductor laser device may alternatively be formed by arraying a plurality of blue semiconductor laser elements and a plurality of green semiconductor elements (as well as a plurality of red semiconductor elements).

While the projector includes the optical system having the liquid crystal panels or the DMD in the aforementioned second embodiment, the present invention is not restricted to this. According to the present invention, the projector may simply include modulation means, and may be formed to include an optical system having a scanning mirror, for example.

What is claimed is:

1. A semiconductor laser device comprising:
a substrate;
a green semiconductor laser element, formed on a surface of said substrate, including a first active layer having a first major surface of a semipolar plane; and
a blue semiconductor laser element, formed on a surface of said substrate, including a second active layer having a second major surface of a surface orientation substantially identical to said semipolar plane, wherein
said first active layer includes a first well layer having a compressive strain and having a thickness of at least about 3 nm, and said second active layer includes a second well layer having a compressive strain.

2. The semiconductor laser device according to claim 1, wherein
said first active layer and said second active layer are made of nitride-based semiconductors.

3. The semiconductor laser device according to claim 1, wherein
said first well layer is made of a nitride-based semiconductor containing In.

4. The semiconductor laser device according to claim 3, wherein
said first well layer is made of InGaN.

5. The semiconductor laser device according to claim 4, wherein
an In composition in said first well layer is at least about 30%.

6. The semiconductor laser device according to claim 1, wherein
said second well layer is made of a nitride-based semiconductor containing In.

7. The semiconductor laser device according to claim 6, wherein
said second well layer is made of InGaN.

8. The semiconductor laser device according to claim 1, wherein
said first well layer and said second well layer are made of nitride-based semiconductors containing In, and
an In composition in said first well layer is larger than an In composition in said second well layer.

9. The semiconductor laser device according to claim 1, wherein
a thickness of said first well layer is larger than a thickness of said second well layer.

10. The semiconductor laser device according to claim 1, wherein
said semipolar plane is a plane inclined toward a (0001) plane or a (000-1) plane by at least about 10° and not more than about 70°.

11. The semiconductor laser device according to claim 10, wherein
said semipolar plane is substantially a (11-22) plane.

12. The semiconductor laser device according to claim 1, wherein
said green semiconductor laser element and said blue semiconductor laser element further include light guides extending in directions projecting [0001] directions on said major surfaces of semipolar planes.

13. The semiconductor laser device according to claim 1, wherein
said green semiconductor laser element further includes a first light guide layer containing In formed on at least either a side of one surface or a side of another surface of said first active layer,
said blue semiconductor laser element further includes a second light guide layer containing In formed on at least either a side of one surface or a side of another surface of said second active layer, and
an In composition in said first light guide layer is larger than an In composition in said second light guide layer.

14. The semiconductor laser device according to claim 1, wherein
said green semiconductor laser element further includes a first carrier blocking layer containing Al formed on at least either a side of one surface or a side of another surface of said first active layer,
said blue semiconductor laser element further includes a second carrier blocking layer containing Al formed on at least either a side of one surface or a side of another surface of said second active layer, and
an Al composition in said first carrier blocking layer is larger than an Al composition in said second carrier blocking layer.

15. The semiconductor laser device according to claim 1, wherein
said green semiconductor laser element further includes a first cladding layer containing Al formed on at least either a side of one surface or a side of another surface of said first active layer,
said blue semiconductor laser element further includes a second cladding layer containing Al formed on at least either a side of one surface or a side of another surface of said second active layer, and
an Al composition in said first cladding layer is larger than an Al composition in said second cladding layer.

16. The semiconductor laser device according to claim 1, further comprising a red semiconductor laser element bonded to at least any of said blue semiconductor laser element, said green semiconductor laser element and said substrate.

17. The semiconductor laser device according to claim 16, wherein
said red semiconductor laser element is bonded to said substrate in a junction-down manner.

18. A display comprising:
a semiconductor laser device including a substrate, a green semiconductor laser element, formed on a surface of said substrate, including a first active layer having a first major surface of a semipolar plane and a blue semiconductor laser element, formed on a surface of said substrate, including a second active layer having a second major surface of a surface orientation substantially identical to said semipolar plane; and
means for modulating light emitted from said semiconductor laser device, wherein
said first active layer includes a first well layer having a compressive strain and having a thickness of at least about 3 nm, and said second active layer includes a second well layer having a compressive strain.
